(19) United States
(12) Patent Application Publication
(10) Pub. No.: US 2026/0107490 A1
(43) Pub. Date: Apr. 16, 2026

(54) POSITIVE-ON AND NEGATIVE-OFF SUBSTRATE BIASING FOR A TRANSISTOR STRUCTURE THAT USES A TWO-DIMENSIONAL ELECTRON GAS

(71) Applicant: Infineon Technologies Austria AG, Villach (AT)

(72) Inventors: Iman ABDALI MASHADI, Ottawa (CA); Iqbal Preet SINGH, Kanata (CA); Vineet UNNI, Kanata (CA); Thomas William MACELWEE, Nepean (CA); Gourab SABUI, Fremont, CA (US); Marco ZUNIGA, Berkeley, CA (US)

(21) Appl. No.: 18/913,308

(22) Filed: Oct. 11, 2024

(51) Int. Cl. H10D 30/47; H10D 30/01; H10D 62/85

(52) U.S. Cl. CPC H10D 30/475; H10D 30/015; H10D 62/8503

(57) ABSTRACT

A transistor that includes a biasing circuit that biases a substrate of the transistor to a positive voltage when the transistor is on, and to a negative voltage when the transistor is off. The transistor comprises a barrier semiconductor layer and a channel semiconductor layer immediately beneath the barrier semiconductor layer to form a heterojunction interface with the barrier semiconductor layer, the heterojunction inducing a two-dimensional electron gas (2DEG) within the channel semiconductor layer. A semiconductor substrate is beneath and rigidly coupled to the channel semiconductor layer and the barrier semiconductor layer. A substrate contact layer is disposed immediately beneath the semiconductor substrate. The substrate contact layer is electrically disconnected from the source contact to allow for a different voltage to be applied to the substrate contact layer as compared to the source contact.

### BACKGROUND

Electronic circuits typically include transistors, which are devices that function as electronic switches that regulate or control current flow in portions of the circuit. One type of transistor is a field-effect transistor in which a voltage is applied to a gate terminal to turn the transistor on and off. A semiconductor channel region is disposed between the drain terminal and the source terminal. When the transistor is on, current flows through the semiconductor channel region between the source terminal and the drain terminal. When the transistor is off, lesser or no current flows through the semiconductor channel region between the source terminal and the drain terminal. The gate terminal is disposed over the semiconductor channel region between the source terminal and the drain terminal. Voltage on the gate terminal generates a field that affects whether the semiconductor channel region conducts current—hence the term “field-effect transistor”.

Silicon has traditionally been used to fabricate transistors. However, wider bandgap semiconductor material may be used to fabricate transistors that conduct higher power and operate at higher efficiency than silicon transistors. Silicon carbide (SiC), Aluminum Nitride (AlN) Zinc Oxide (ZnO), Gallium Arsenide (GaAs) and Gallium Nitride (GaN) are each examples of wide bandgap semiconductor materials that can be used in power electronics. One way to use such wider bandgap semiconductor materials is to form two layers of different semiconductor materials to therebetween form a heterojunction.

These two semiconductor materials may have sufficiently different bandgap profiles such that when brought together, the joined conductive band of the bandgap drops below the Fermi level just within the channel semiconductor layer. This means that electrons may freely flow within this region. This region is thin in depth and forms a plane parallel to the upper surface of the channel region. Thus, this region is called a “Two-Dimensional Electron Gas” (or “2DEG”) (emphasizing “Two-Dimensional”) to emphasize its planar form. Furthermore, this region is also referred to as a “Two-Dimensional Electron Gas” (emphasizing “Electron Gas”) due to the high mobility of electrons in this region. Thus, the 2DEG is highly conductive. The 2DEG may form the channel region of a power semiconductor with relatively low resistance to allow passage of a large amount of current.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Embodiments described herein relate to a transistor that includes a substrate that is biased to a positive voltage (with respect to a source voltage) when the transistor is on, and to a negative voltage (with respect to the source voltage) when the transistor is off. For example, the transistor comprises a barrier semiconductor layer and a channel semiconductor layer immediately beneath the barrier semiconductor layer to form a heterojunction interface with the barrier semiconductor layer. The heterojunction induces a two-dimensional electron gas (2DEG) within the channel semiconductor layer. A source contact and a drain contact are each in conductive contact with the 2DEG. A gate terminal is proximate to the 2DEG such that voltages applied to the gate terminal control whether the 2DEG is continuous between the source contact and the drain contact.

A semiconductor substrate is beneath and rigidly coupled to the channel semiconductor layer and the barrier semiconductor layer. For example, the channel semiconductor layer and barrier semiconductor layer may be epitaxially grown on layers supported by the semiconductor substrate. A substrate contact layer is disposed immediately beneath the semiconductor substrate. The substrate contact layer is electrically disconnected or disconnectable from the source contact to allow for a different voltage to be applied to the substrate contact layer as compared to the source contact.

The transistor structure also includes a biasing circuit that is configured to bias the substrate contact layer. Specifically, the biasing circuit biases the substrate to a positive voltage with respect to the source voltage when the transistor is on, and to a negative voltage with respect to the source voltage when the transistor is off. By applying a positive voltage to the substrate when the transistor is on, the 2DEG charge may be increased, allowing the saturation current of the transistor structure to be increased, thereby allowing more power to be transferred. Furthermore, the dynamic on resistance of the transistor is reduced. On the other hand, by applying a negative voltage to the substrate when the transistor is off, increases in the on-resistance of the transistor as it ages (sometimes referred to as Rdson aging) may be substantially reduced.

These combined effects may even allow the dimensions of the transistor to be smaller in footprint. A reduced transistor footprint means that more transistors can be fabricated on a single wafer. Furthermore, since the area of the transistor is reduced, the opportunity for manufacturing defects is reduced, and yield may potentially be increased. That is, there is the potential to reduce the percentage of unusable or defective transistors present on a wafer. Furthermore, as the transistor passes power more efficiently for longer, the transistor reduces energy waste, thereby reducing carbon footprint in the environment. Also, as the transistor may potentially be made smaller and/or last longer, precious material resources are more carefully used.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 is an illustration of an embodiment of a transistor in accordance with the principles described herein.

FIG. 2 illustrates a transistor that is a specific example of the transistor of FIG. 1, and which is an example of a High Electron Mobility Transistor (HEMT) (a type of “power transistor”) that may be used to pass high amounts of power.

FIG. 3 illustrates a biasing environment that includes a power transistor (such as that of FIG. 2), as well as a biasing circuit (which represents an example of the biasing circuits of FIGS. 1 and 2) that is configured to use the drain voltage of the power transistor to generate an alternating substrate biasing voltage that is positive when the power transistor is on, and negative when the power transistor is off.

FIG. 4 illustrates a circuit diagram of a stable voltage generator that is an example of the stable voltage generator of FIG. 3.

FIG. 5 illustrates an example inverter circuit that is an example of the inverter circuit of FIG. 3.

FIG. 6 illustrates an example voltage level shifter that is an example of the voltage level shifter of FIG. 3.

FIG. 7 illustrates a cross-sectional view of each of a power transistor, a low-voltage transistor, a resistor, and a capacitor, each formed on the same silicon substrate that the power transistor is formed on.

FIG. 8 illustrates a package that includes an integrated circuit in which the power transistor and all of the biasing circuit are formed monolithically (with the exception of a capacitor).

FIG. 9 illustrates a biasing circuit that is similar to the biasing environment of FIG. 3, except with additional circuitry used to negatively bias the substrate in case of a short circuit;

FIG. 10A illustrates a flowchart of a method for positively biasing the substrate of the power transistor in case of detecting a pre-condition for such a positive bias;

FIG. 10B illustrates a flowchart of a method for negatively biasing the substrate of the power transistor in case of detecting a pre-condition for such a positive bias;

FIG. 11 illustrates a package structure in which a die that has substrate biasing circuitry monolithically formed with a power transistor may be packaged.

FIG. 12 illustrates another package structure in which the die may be packaged.

FIG. 13 illustrates yet another package structure in which the die may be packaged.

### DETAILED DESCRIPTION

Embodiments described herein relate to a transistor that includes a substrate that is biased to a positive voltage (with respect to a source voltage) when the transistor is on, and to a negative voltage (with respect to the source voltage) when the transistor is off. For example, the transistor comprises a barrier semiconductor layer and a channel semiconductor layer immediately beneath the barrier semiconductor layer to form a heterojunction interface with the barrier semiconductor layer. The heterojunction induces a two-dimensional electron gas (2DEG) within the channel semiconductor layer. A source contact and a drain contact are each in conductive contact with the 2DEG. A gate terminal is proximate to the 2DEG such that voltages applied to the gate terminal control whether the 2DEG is continuous between the source contact and the drain contact.

A semiconductor substrate is beneath and rigidly coupled to the channel semiconductor layer and the barrier semiconductor layer. For example, the channel semiconductor layer and barrier semiconductor layer may be epitaxially grown on layers supported by the semiconductor substrate. A substrate contact layer is disposed immediately beneath the semiconductor substrate. The substrate contact layer is electrically disconnected or disconnectable from the source contact to allow for a different voltage to be applied to the substrate contact layer as compared to the source contact.

The transistor structure also includes a biasing circuit that is configured to bias the substrate contact layer. Specifically, the biasing circuit biases the substrate to a positive voltage with respect to the source voltage when the transistor is on, and to a negative voltage with respect to the source voltage when the transistor is off. Hereinafter, when describing the application of a “positive voltage” or a “negative voltage” to the substrate, it will be understood that this is with respect to the source voltage.

By applying a positive voltage to the substrate when the transistor is on, the 2DEG charge may be increased, allowing the saturation current of the transistor structure to be increased, thereby allowing more power to be transferred. In addition, positive voltage applied to the substrate can improve the dynamic threshold voltage of the transistor (which is the varying of the threshold voltage duration operation due to a variety of factors including trapping and de-trapping of charge carriers). Furthermore, the dynamic on resistance of the transistor is reduced. On the other hand, by applying a negative voltage to the substrate when the transistor is off, increases in the on-resistance of the transistor as it ages (sometimes referred to as Rdson aging) may be substantially reduced. Rdson aging occurs with some types of semiconductors that are subject to high voltages.

These combined effects may even allow the dimensions of the transistor to be smaller in footprint. A reduced transistor footprint means that more transistors can be fabricated on a single wafer. Furthermore, since the area of the transistor is reduced, the opportunity for manufacturing defects is reduced, and yield may potentially be increased. That is, there is the potential to reduce the percentage of unusable or defective transistors present on a wafer. Furthermore, as the transistor passes power more efficiently for longer, the transistor reduces energy waste, thereby reducing carbon footprint in the environment. Also, as the transistor may potentially be made smaller and/or last longer, precious material resources are more carefully used.

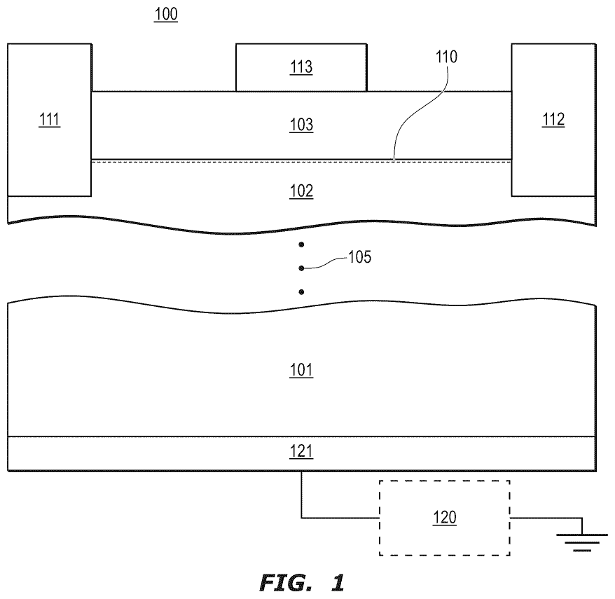

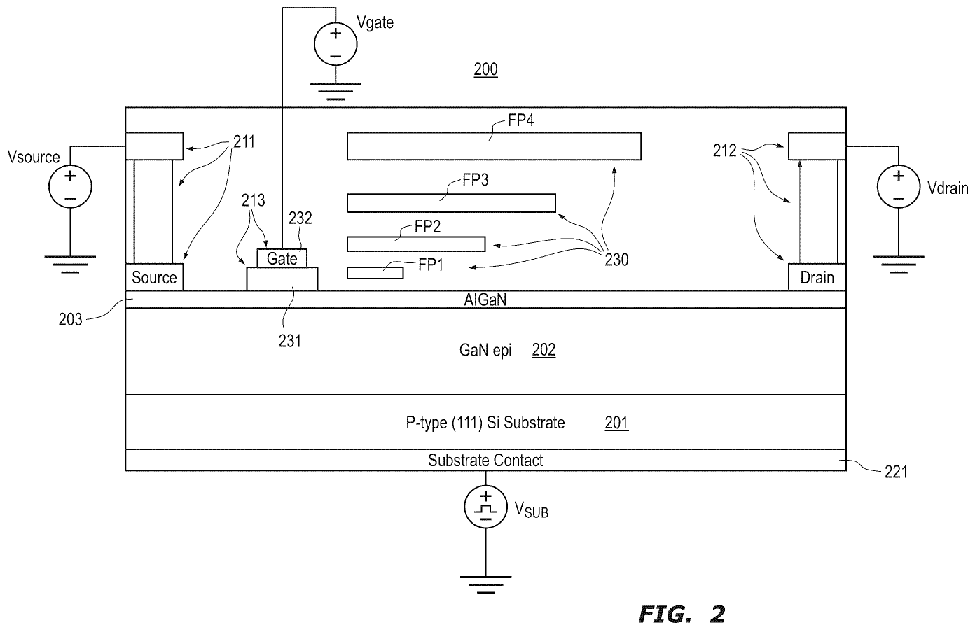

FIG. 1 is an illustration of an embodiment of a transistor 100 in accordance with the principles described herein. The transistor 100 is a simplified diagram used to describe the general principle of transistors that use 2DEGs (High Electron Mobility Transistors or “HEMTs”) and substrate biasing of the same. A more specific example will be provided with respect to FIG. 2, which illustrates more concretely more details of a HEMT, which is a type of a power transistor.

The transistor 100 may be formed by epitaxially growing an epitaxial stack on a substrate. In this description and in the claims, a direction of growth of this epitaxial stack will be referred to as a “vertical” direction. Consequently, terms describing relative vertical position (such as “beneath”, “below”, and “above” and so forth) are with respect to this vertical direction. For instance, if a second layer is epitaxially grown on the first layer, the second layer will be “above” the first layer, and the first layer will be “beneath”the second layer.

Returning to FIG. 1, the transistor 100 includes a semiconductor substrate 101 that forms a foundation on which further layers may be epitaxially grown to formulate part of a transistor structure. The semiconductor substrate 101 may be any semiconductor, including silicon. Layers epitaxially grown on top of the semiconductor substrate 101 will be referred to hereinafter as an “epitaxial stack”.

The epitaxial stack includes a channel semiconductor layer 102 epitaxially grown using the semiconductor substrate 101 as a foundation. The channel semiconductor layer 102 may be comprised of any suitable semiconductor, including Gallium Nitride (GaN). The ellipsis 105 represents that there may be any number of layers in the epitaxial stack between the semiconductor substrate 101 and the channel semiconductor layer 102. As an example only, strain relief layers may be formed between the semiconductor substrate and the channel semiconductor layer 102 to thereby improve the mechanical stability and electrical performance of the transistor 100. Nevertheless, the principles described herein are not limited to what (if any) layers are between the semiconductor substrate 101 and the channel semiconductor layer 102. Suffice it to say that the semiconductor substrate 101 is rigidly coupled to the channel semiconductor layer 102 to provide adequate support for the channel semiconductor layer 102 as well as the remainder of the epitaxial stack, in the sense that all epitaxial layers are coupled to a substrate on which they are grown.

A barrier semiconductor layer 103 is epitaxially grown on the channel semiconductor layer 102 such that the barrier semiconductor layer 103 is immediately above the channel semiconductor layer 102. A heterojunction interface is present between the channel semiconductor layer 102 and the barrier semiconductor layer 103. The barrier semiconductor layer 103 may be comprised of any suitable semiconductor such as Aluminum Gallium Nitride (AlGaN). The differences in the bandgap profiles of the channel semiconductor layer 102 (e.g., GaN) and the barrier semiconductor layer 103 (e.g., AlGaN) are such that the conduction band edge of the channel semiconductor is pulled downwards near the heterojunction interface, thus creating an energy potential well that dips below the Fermi level vertically just within the channel semiconductor layer 102. Because the well is below the Fermi level, free electrons exist in this well, forming a highly conductive two-dimensional electron gas (“2DEG”) 110, represented by the horizontal dashed line in FIG. 1.

The vertical thickness of the region in which such free electrons exist correspond to the short vertical span of the well that dips below the Fermi level. Thus, the 2DEG is vertically thin. However, the region is planar in the horizontal plane. Thus, this region is called a “Two-Dimensional” Electron Gas to emphasize its planar form. The reference to “Electron Gas” in the term is to emphasize that the electrons in the 2DEG have high mobility. The 2DEG is also referred to as a “sea of electrons” also emphasizing the mobility of the electrons in the 2DEG. The 2DEG may form the channel region of a power semiconductor to allow passage of high currents with relatively low resistance. Thus, 2DEGs are indispensable in high-frequency and high-power electronics, with applications in devices such as HEMTs.

A source contact 111 is in conductive contact with the 2DEG 110, which means that electrons may flow freely between the source contact 111 and the 2DEG 110 (see leftmost portion of the 2DEG 110 as shown in FIG. 1). This may be because source contact 111 and the 2DEG 110 are in direct contact (as shown in FIG. 1), or perhaps they are not in direct contact, but close enough that the electrons may still flow between the source contact 111 and the 2DEG 110. Likewise, the drain contact 112 is also in conductive contact with the 2DEG 110 (see rightmost portion of the 2DEG 110 as shown in FIG. 1). If the 2DEG 110 is continuous between the source contact 111 and the drain contact 112, the 2DEG 110 serves as a channel through which electrons may flow between the source contact 111 and the drain contact 112.

A gate terminal 113 is proximate the 2DEG 110 such that voltages applied to the gate terminal 113 (or more specifically the electrical fields caused by those voltages) control whether the 2DEG 110 is continuous between the source contact 111 and the drain contact 112. When the gate terminal 113 is off, the 2DEG 110 is discontinuous underneath the gate terminal 113, and when the gate terminal 113 is on, then the 2DEG 110 is continuous underneath the gate terminal 113. If the transistor 100 is an enhancement mode transistor, the transistor 100 is off when no voltage is applied to the gate terminal 113, and on when a sufficient positive voltage is applied to the gate terminal 113. If the transistor 100 is a depletion mode transistor, the transistor 100 is on when no voltage is applied to the gate terminal 113 and off when a sufficient negative voltage is applied to the gate terminal 113. Thus, by controlling the continuity of the 2DEG 110 between the source contact 111 and the drain contact 112, voltages applied to the gate terminal 113 control whether the transistor 100 is on or off. As the transistor 100 using a 2DEG, the transistor 100 is a HEMT.

The transistor 100 is a four-terminal device in which the semiconductor substrate 101 is a fourth terminal that is disconnected or at least disconnectable from the source contact 111. That is to say, the voltage (referred to herein as a “bias voltage” or a “bias”) that is applied to the semiconductor substrate 101 may be different than the voltage that is applied to the source contact 111. For this purpose, a substrate contact 121 is beneath the semiconductor substrate 101 and may be electrically disconnected from the source contact 111. This will allow a biasing circuit 120 to apply a bias via the substrate contact 121 to the semiconductor substrate 101 that is independent from the voltage present at the source contact 111. Electrically disconnecting the substrate contact 121 from the source contact 111 allows for the biasing circuit to bias the semiconductor substrate 101 to a positive voltage when the transistor 100 is on, and to a negative voltage when the transistor is off. More regarding the benefits of doing this will be described further below.

For some applications, both positive and negative substrate biasing are important, particularly for high-current applications where saturation current is a critical factor. However, for low-current applications where saturation current is not a concern, instead of biasing the substrate with a positive voltage when on. The substrate may simply be at 0 volts when on, whilst being biased to a negative voltage when off.

FIG. 2 illustrates a transistor 200 that is a specific example of the transistor 100 of FIG. 1. The P-type (111) substrate 201 is an example of the semiconductor substrate 101 of FIG. 1, the GaN epitaxial layer 202 is an example of the channel semiconductor layer 102 of FIG. 1, and the AlGaN layer 203 is an example of the barrier semiconductor layer 103 of FIG. 1. Moreover, the source contact structure 211 (having a voltage Vsource applied thereto) is an example of the source contact 111 of FIG. 1, the drain contact structure 212 (having a voltage Vdrain applied thereto) is an example of the drain contact 112 of FIG. 1, the gate structure 213 (having a voltage Vgate applied thereto) is an example of the gate terminal 113 of FIG. 1, and the substrate contact 221 (having am alternating voltage V_{SUB} applied thereto) is an example of the substrate contact 121 of FIG. 1.

The gate structure 213 includes a p-doped GaN layer 231 which causes the 2DEG to be discontinuous under the gate when there is no voltage applied to a conductive gate 232, thus causing the transistor 200 to be an enhancement mode transistor. Thus, as represented by voltages Vsource, Vdrain, Vgate, and V_{SUB}, four different voltages may be applied to four different terminals of the transistor 200. Accordingly, the transistor 200 is a four terminal HEMT. A field plate structure 230 is also shown (which includes field plates FP1, FP2, FP3 and FP4), which allows for management of the electrical field profile in the 2DEG.

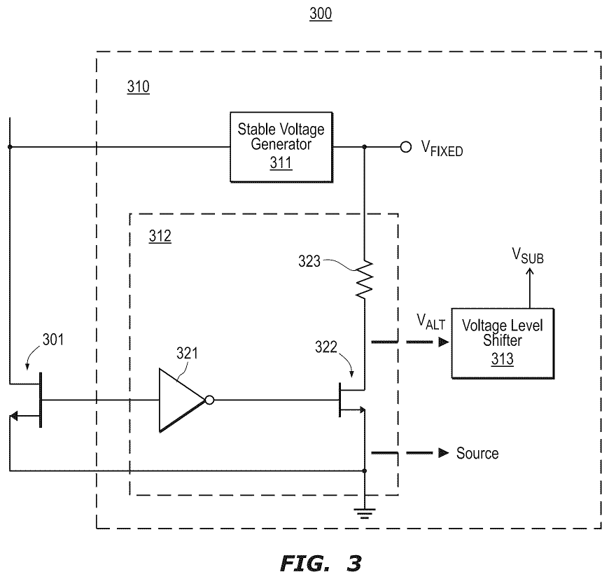

FIG. 3 illustrates a biasing environment 300 that includes the power transistor 301 as well as a biasing circuit 310. This figure represents just one example of how the power transistor can be biased, and the principles described herein are in no way limited to FIG. 3. As an example only, the power transistor 301 may be the transistor 100 of FIG. 1, or the transistor 200 of FIG. 2. In the case of the power transistor 301 being the transistor 100 of FIG. 1, the biasing circuit 310 is an example of the biasing circuit 120 of FIG. 1. In the case of the power transistor 301 being the transistor 200 of FIG. 2, the biasing circuit 310 is an example of the voltage source that generates the alternating voltage V_{SUB} of FIG. 2.

The biasing circuit 310 generates the biasing voltage V_{SUB} using the drain voltage of the power transistor 301. The biasing voltage V_{SUB} is positive when the power transistor 301 is on, and negative when the power transistor 301 is off. The biasing voltage V_{SUB} is applied to the substrate of the power transistor 301. As an example, in the case of the power transistor 301 being the transistor 100 of FIG. 1, the biasing circuit 310 applies the biasing voltage V_{SUB} to the substrate contact 121 of FIG. 1. In the case of the power transistor 301 being the transistor 200 of FIG. 2, the biasing circuit 310 applies the biasing voltage V_{SUB} to the substrate contact 221 of FIG. 2.

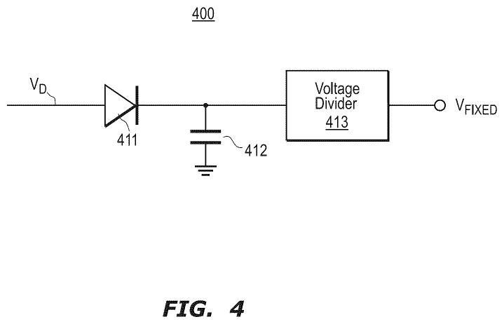

The biasing circuit 310 includes a stable voltage generator 311, and alternating voltage generator 312, and a voltage level shifter 313. The stable voltage generator 311 is connected to the drain of the power transistor 301, and generates a stable relatively fixed voltage V_{FIXED} using power from the drain of the power transistor 301 while drawing only a little current from the drain of the power transistor 301. A specific example of a stable voltage generator 311 will be described with respect to FIG. 4. However, FIG. 4 represents just one example of a stable voltage generator, and the principles described herein are in no way limited to FIG. 4.

The voltage V_{FIXED} should be the difference in voltage between the positive voltage applied to the substrate when the power transistor 301 is on, and the negative voltage applied to the substrate when the power transistor 301 is off. Furthermore, the voltage V_{FIXED} will be below the drain off-voltage of the transistor. As an example, suppose that the power transistor 301 has a drain voltage of 650 volts when off, that the positive bias voltage is 180 volts, and the negative bias voltage is −120 volts. In that case, the voltage V_{FIXED} would be 300 volts, being less than the drain off-voltage of 650 volts of the power transistor 301, and being the difference between the positive bias voltage of 180 volts and he negative bias voltage of negative 120 volts.

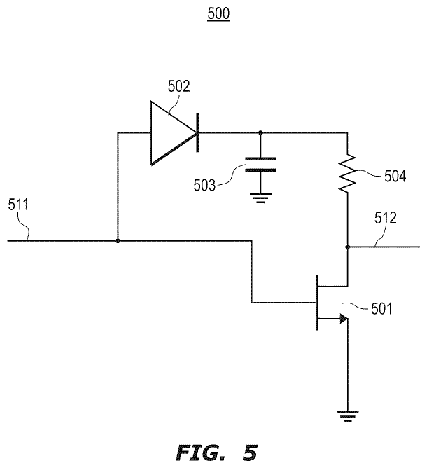

The alternating voltage generator 312 includes an inverter circuit 321, a transistor 322, and a resistor 323. As an example, the inverter circuit 321 may be an inverter. More details about an example circuit structure of the inverter circuit 321 will be described below with respect to FIG. 5. In any case, the inverter circuit 321 outputs a high signal when its input is low, and outputs a low signal when its input is high. The inverter circuit 321 has an input terminal connected to the gate terminal of the power transistor 301, and an output terminal connected to a gate terminal of the transistor 322. Thus, if a high signal is applied to the gate terminal of the power transistor 301, a low signal is applied to the gate terminal of the transistor 322, and vice versa.

As previously mentioned, when a high signal is applied to the gate terminal of the power transistor 301, a low signal is applied to the gate terminal of the other transistor 322, which causes the transistor 322 to be off. Accordingly, even though resister 323 is present between the drain terminal of the transistor 322 and the voltage V_{FIXED}, there is little or no current passing through the resistor 323, and thus the drain terminal of the transistor 322 still substantially assumes the voltage V_{FIXED}. Therefore, when the power transistor 301 is on, the voltage V_{FIXED} is applied as the high part of an alternating voltage V_{ALT} to the voltage level shifter 313.

On the other hand, when a low signal is applied to the gate terminal of the power transistor 301, a high signal is applied to the gate terminal of the other transistor 322, which causes the transistor 322 to be on. In this state, because the resistor 323 has a high resistance compared to the on-resistance of the transistor 322, the voltage at the drain terminal of the transistor 322 goes quite low (perhaps on the order of a few volts). Thus, when the power transistor 301 is off, the alternating voltage V_{ALT} assumes a voltage close to zero volts. Thus, the alternating voltage generator 312 applies an alternating voltage V_{ALT} to the voltage level shifter that is high when the power transistor 301 is on, and substantially zero when the power transistor 301 is off. For instance, in the previous example in with the voltage V_{FIXED} is 300 volts, the alternating voltage generator 312 would output a signal V_{ALT} that is 300 volts when the power transistor 301 is on, and ground when the power transistor 301 is off.

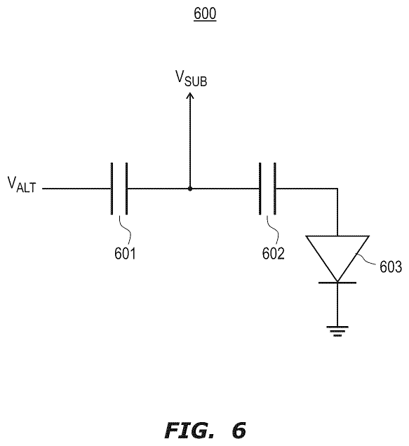

The voltage level shifter 313 receives the alternating voltage V_{ALT}, and shifts the voltage down to generate an alternating voltage V_{SUB}. The amount of shifting downward is the amount of negative bias voltage to be applied to the substrate. For instance, in the example in which positive 180 volts is to be applied to the substrate when the power transistor 301 is on, and negative 120 volts is applied to the substrate when the power transistor 301 is off, the voltage level shifter 313 may shift the alternating voltage V_{ALT} down by 120 volts to generate the voltage V_{SUB}. Thus, in this example, the alternative voltage V_{SUB} is generated that is positive 180 volts when the power transistor is on, and negative 120 volts when the power transistor is on, thus applying the right and appropriately timed biasing voltages to the substrate of the power transistor. However, any positive and negative biasing voltages may be achieved by having the stable voltage generator 311 generate an appropriate fixed voltage V_{FIXED} that is the difference between the desired positive and negative bias voltages, and by likewise having the voltage level shifter 313 shift downwards by the amount of the desired negative bias voltage. FIG. 6 illustrates an example circuit structure of the voltage level shifter 313.

FIG. 4 illustrates a circuit diagram of a stable voltage generator 400 that may be used as an example of the stable voltage generator 311 of FIG. 3. The stable voltage generator 400 receives as input the voltage V_{D} that is at the drain of the power transistor 301, and generates the stable voltage V_{FIXED}. The stable voltage generator 400 includes a rectifier 411, then a ground-connected capacitor 412, and then a voltage divider 413 connected in that order in series from the input to the output. The rectifier 411 may be any circuit element that outputs a rectified form of its input voltage. As an example, the rectifier 411 may be a diode. The voltage divider 413 could be, for example, resistors connected in series between the input of the voltage divider and ground, where the output of the voltage divider is one of the intermediate nodes between the resistors. Alternatively, the voltage divider 413 could be, for example, capacitors connected in series between the input of the voltage divider and ground, where the output of the voltage divider is one of the intermediate nodes between the capacitors.

When the power transistor 301 is off, the drain voltage V_{D} is high, allowing charge to flow (from left to right in FIG. 4) through the rectifier 411, and thus charge is provided to the upper terminal of the capacitor 412 replenishing the charge on the capacitor 412 and thereby stabilizing the voltage across the capacitor 412. That voltage is then provided to a voltage divider 413 that outputs the stable voltage V_{FIXED} that is some fraction of the voltage across the capacitor 412. On the other hand, when the power transistor 301 is on, the drain voltage V_{D} is relatively low, and thus the rectifier 411 is reverse-biased, thereby allowing the capacitor 412 to keep its charge. Charge is drawn at a low rate into the alternating voltage generator. However, the capacitor 412 is sized to be large enough that the capacitor still substantially maintains its voltage despite some small current drawn.

FIG. 5 illustrates an example inverter circuit 500 that may be used to implement the inverter circuit 321 of FIG. 3. Of course, there are many ways to implement an inverter, so this is just an example. The inverter circuit 500 includes a transistor 501, a diode 502, a capacitor 503, and a resistor 504. The input 511 of the inverter circuit 500 is connected to the gate of the power transistor 301 (as shown in FIG. 3). Accordingly, the on-off pulse that drives the gate of the power transistor 301 is also applied to the input 511 of the inverter circuit 500. Due to the diode 502, the capacitor 503 is charged to be close to the on voltage applied to the gate of the power transistor 301. Thus, the capacitor 503 may be charged to be about 5 volts.

When a high voltage is applied to the gate of the power transistor 301 (and to the input 511 of the inverter circuit 500), a high voltage is also applied to the gate of the transistor 501, turning the transistor 501 on. Due to the resistor 504 dominating over the on-resistance of the transistor 501, the output 512 of the inverter circuit 500 is low. Thus, when there is a high voltage (e.g., 5 or 6 volts) applied to the input 511 of the inverter circuit 500, the inverter circuit applies a low voltage (e.g., substantially ground) to the output 512 of the inverter circuit.

On the other hand, when a low voltage is applied to the gate of the power transistor 301 (and to the input 511 of the inverter circuit 500), a low voltage is also applied to the gate of the transistor 501, turning the transistor 501 off. Since little or no current would then pass through the resistor 504, the output 512 of the inverter circuit 500 would then assume close to the same voltage that is stored across the capacitor 503, which is a relatively high 5 or 6 volts. Thus, when the input 511 of the inverter circuit 500 is low, the output 512 of the inverter circuit 500 is high.

FIG. 6 illustrates an example voltage level shifter 600 that may be used to implement the voltage level shifter 313 of FIG. 3. The voltage level shifter 600 includes a first capacitor 601, a second capacitor 602, and a forward-connected diode 603 connected in that order between the input carrying the alternating signal V_{ALT} and ground. The shifted alternating bias voltage V_{SUB} is drawn from the circuit node between the first capacitor 601 and the second capacitor 602. The amount of voltage shifting may be controlled by sizing the first capacitor 601 and the second capacitor 602 in proper proportion.

The biasing circuit 310 may be monolithic (on the same substrate and using at least some of the same epitaxial layers) as the power transistor 301. This is particularly, true when using the stable voltage generator 400 of FIG. 4 as the stable voltage generator 311 of FIG. 3, the inverter circuit 500 of FIG. 5 as the inverter circuit 321 of FIG. 4, and the voltage level shifter 600 of FIG. 6 as the voltage level shifter 313 of FIG. 3. This is because in that case the biasing circuit 310 only includes four types of circuit elements, 1) a transistor, 2) a resistor, 3) a capacitor, and 4) a diode. However, a diode can be constructed using a transistor by connecting the gate and source of the transistor. Accordingly, biasing circuit 310 may be composed of as few as three types of elements including 1) a transistor, 2) a resistor, and 3) a capacitor. Finally, a capacitor may be implemented using a high voltage transistor connected in diode-configuration (with its gate and source being connected), and in which the drain-to-source parasitic capacitance is used as the capacitor. In this case, the biasing circuit 310 of FIG. 1 may be composed of as few as two elements including 1) transistors, and 2) resistors.

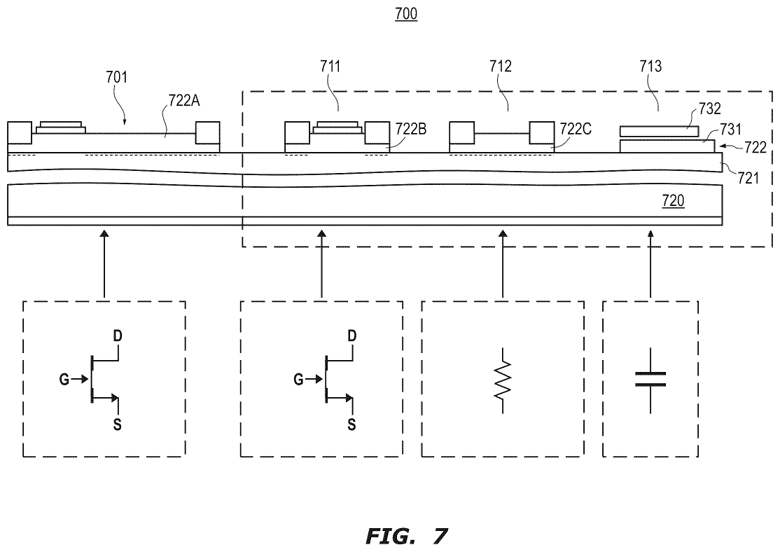

FIG. 7 illustrates a cross-sectional view 700 of each of a power transistor 701, low voltage transistor 711, a resistor 712, and a capacitor 713, each formed on the same silicon substrate 720 that the power transistor 701 is formed on. Furthermore, the power transistor 701, the low voltage transistor 711 and the resistor 712 are each formed of portions of the same epitaxial stack. Specifically, the power transistor 701, the low voltage transistor 711 and the resistor 712 are each structured using a common channel semiconductor layer 721. Furthermore, the power transistor 701 includes a portion 722A of a barrier semiconductor layer 722, the low voltage transistor 711 includes another portion 722B of the barrier semiconductor layer 722, and the resistor 712 includes another portion 722C of the barrier semiconductor layer 722.

The power transistor 701 takes substantially the same form as the transistor 200 of FIG. 2. A 2DEG is represented by a horizontal dashed line, which is discontinuous under the gate of the power transistor 701, but which can be controlled to be selectively continuous by application of voltages to the gate of the power transistor 701. Similarly, the low voltage transistor 711 also uses a 2DEG that is formed from the same heterojunction, where again the continuity of the 2DEG under the gate may be controlled by application of appropriate voltages to the gate. The resistor 712 takes a similar form as the power transistor 701 and low voltage 711, except with no gate structure at all, and thus the 2DEG is always continuous between the two terminals of the resistor. There are other ways to implement the resistor, such as by forming metallization with suitable resistance. The capacitor 713 may be formed using two metal layers 731 and 732 separated by an insulator layer. Alternatively, a capacitor may be implemented using a high voltage transistor that has a lower channel width perpendicular to current flow than the power transistor 701. Another way to implement a capacitor is to use the Coss (or output capacitance) of one of the transistors.

Thus, by forming instances of the transistor 711 and the resistor 712 in the same epitaxial stack as the power transistor 701, and forming the capacitor 713 using metal-insulator-metal (MIM) technology as shown (or composing a capacitor out of the drain-to-source parasitic capacitance of a high voltage transistor), and by forming appropriate connections as for example illustrated in FIGS. 3 through 6, the bias circuit 320 may be formed monolithically with the power transistor 301.

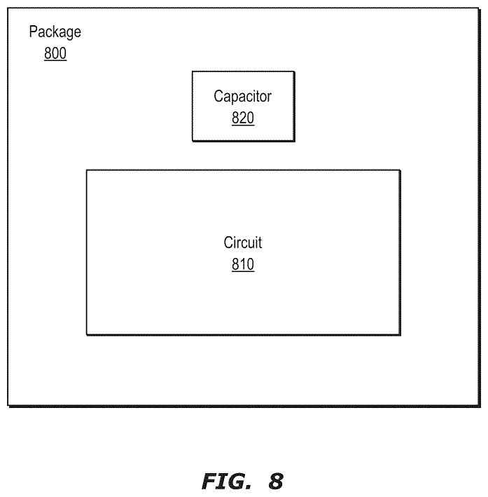

In one embodiment, one or more of the capacitors may be formed off-chip, but still may be packaged within the same package as the other components of the biasing circuit and power transistor. For instance, FIG. 8 illustrates a package 800 that includes an integrated circuit 810 (i.e., a chip) in which the power transistor and all of the biasing circuit are formed monolithically (with the exception of a capacitor). In FIG. 8, the capacitor 820 is a discrete component that is located off-chip, but which is co-packaged with the integrate circuit. Alternatively, even the capacitor may be formed monolithically with the power transistor and the remainder of the biasing circuitry. Alternatively, in a co-packaged approach, the dynamic substrate biasing circuit may be formed in a silicon chip, while the power transistor is implemented on another chip.

The monolithic construction of the bias circuit with the power transistor allows for a streamlined manufacturing process for implementations of substrate biasing. Because the elements used in implementations of the biasing circuit 310 may be relatively small compared to the power transistor, the footprint of implementations of the biasing circuit 310 may be small in comparison to the power transistor 301. Thus, the implementations of the biasing circuit 310 may only marginally (if at all) impact a die area in a monolithic implementation of embodiments described herein. Die area plays a crucial role in determining manufacturing cost and environmental impact, as it directly influences the number of chips that can be produced on a single wafer. Generally, smaller die sizes allow for higher chip yields per wafer, resulting in lower production losses. In some implementations, the monolithic implementation of substrate biasing may have only a very low die penalty.

The principles described herein have benefit both when the transistor is on and the substrate is biased positively, and when the transistor is off and the substrate is biased negatively. When the transistor is on and the substrate is biased positively, for a given drain voltage, the power transistor experiences less leakage current than without positively biasing the substrate. The reduction in leakage current enables a thinner GaN layer. Manufacturing defects arising from a GaN layer that is too thick may thus decrease, enabling an increased yield in the manufacturing process. Thus, the power transistor with the biasing circuit in accordance with the principles described herein may enable greater yields of the manufacturing process, and less material waste during manufacturing.

Furthermore, the transistor could be continuous use, which may include running the transistor for a long time—hours, days, or weeks straight. The transistor runs in the linear mode when the outputted current increases linearly with the voltage applied. The transistor runs in the saturation mode when the outputted current increases much less, if at all, with increases with the voltage applied. In this mode, the outputted current may also be called the saturation current of the transistor. Saturation current may be an important characteristic of a transistor. The higher the saturation current of the transistor, the more power the transistor may deliver when operating in saturation mode. Additionally, the higher the saturation current, the more efficient the transistor may be at delivering that power, as more current is being driven at a given voltage. It may thus be desirable to achieve higher saturation currents for any given transistor, as doing so may increase both the efficiency of the transistor in delivering power and the capability of the transistor to deliver power. By positively biasing the substrate of the transistor when the transistor is on, the saturation current may be increased. Furthermore, in the linear region, the on-resistance of the transistor is reduced.

On the other hand, when the transistor is off and the substrate is biased negatively, Rdson aging may be significantly reduced, extending the life of the transistor, and also allowing the transistor to operate at higher efficiencies for longer. When the transistor is a GaN HEMT operating at 650 V, at least for some manufacturing processes, the positive bias voltage may be at least 40 volts, and at least 100 volts, but perhaps several hundred volts. Also, the negative bias voltage may be more negative than negative 40 volts, more negative than negative 100 volts, or perhaps may be negative 120 volts. The precise amount of optimal positive bias voltage and optimal negative voltage is anticipated to be highly dependent on the materials used and the manufacturing process.

Thus, a transistor with a biased substrate as described herein may enable a number of benefits including a higher saturation current, a reduced transistor structure footprint, and a higher yield in the manufacturing process. However, there are other benefits to applying a negative bias voltage to the substrate of the transistor, such as to quickly turn off the power transistor when a short is detected. Since the transistor used in the bias circuit is a high voltage transistor, the capacitance of the bias circuit is much lower than the gate capacitance of the power transistor. Thus, the substrate may be negatively biased much more quickly than the power transistor may be turned off. Since a short condition may quickly destroy the power transistor, speed is a critical issue. In the case of a short, the substrate of the power transistor may be quickly biased negative, thereby thinning or depleting the 2DEG thereby stopping current from flowing through the power transistor even before the power transistor is otherwise turned off using the gate of the power transistor.

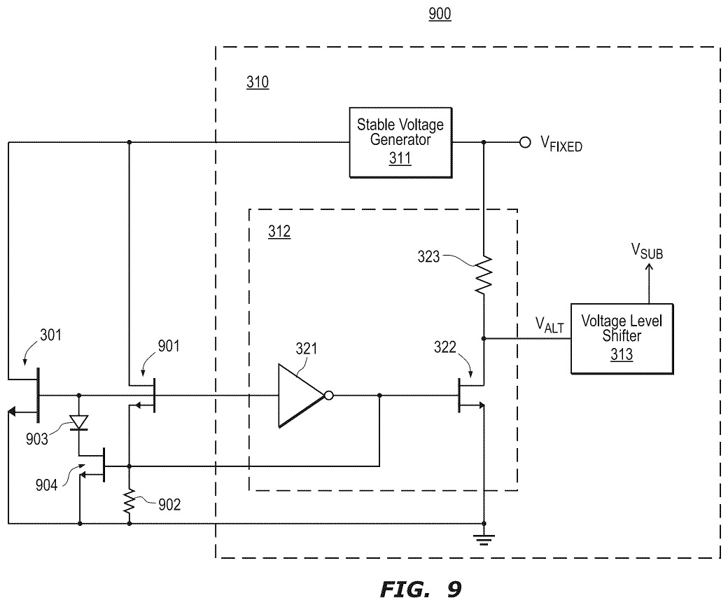

FIG. 9 illustrates a biasing environment 900 that is similar to the biasing environment 300 of FIG. 3, except with the low voltage transistor 901 acting as a short detection, and with the resistor 902, the diode 903 and the low voltage transistor 904 together acting to bias the gate of the low voltage transistor 322 high when a short is detected. That is, when the power transistor 301 is shorted, the low voltage transistor 901 turns on and the voltage at the gate of transistor 901 and 322 goes high, thus turning the transistor 322 on. The signal V_{ALT} then substantially immediately goes low (due to the very low gate capacitance of the transistor 322), and thus V_{SUB} goes low substantially immediately, thus negatively biasing the substrate of the power transistor 301 even though the power transistor 301 is still on but will imminently be turned off. As with all other figures, however, this figure is merely an example of a biasing environment. The principles described herein are not limited to any particular circuit implementation for applying a bias to the substrate.

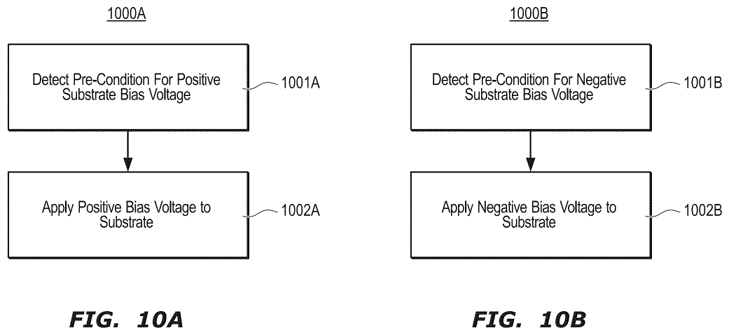

FIG. 10A illustrates a flowchart of a method 1000A for biasing a substrate of a power transistor, such as the transistor 200 of FIG. 2. The method 1000A includes detecting a pre-condition for applying a positive bias voltage to the substrate contact layer (act 1001A), and in response applying the positive bias voltage to the substrate contact layer (act 1002A). FIG. 10B illustrates a flowchart of a method 1000B for biasing a substrate of a power transistor, which includes detecting a pre-condition for applying a negative bias voltage to the substrate contact layer (act 1001B), and in response applying the negative bias voltage to the substrate contact layer (act 1002B).

The methods 1000A and 1000B may be alternately performed upon alternately detecting the pre-condition for applying the positive bias volage and the pre-condition for applying the negative bias voltage. For instance, the pre-condition for applying the positive bias voltage to the substrate may be that the power transistor is turned on, and the pre-condition for applying the negative voltage could be that the power transistor is turned off. If the power transistor is turned on and off repeatedly, the method 1000A and 1000B are likewise repeatedly performed to alternately bias positive and negative the substrate of the power transistor. In the alternative of FIG. 9, an additional pre-condition for applying the negative bias voltage to the substrate of the power transistor could be that a short is detected in the power transistor.

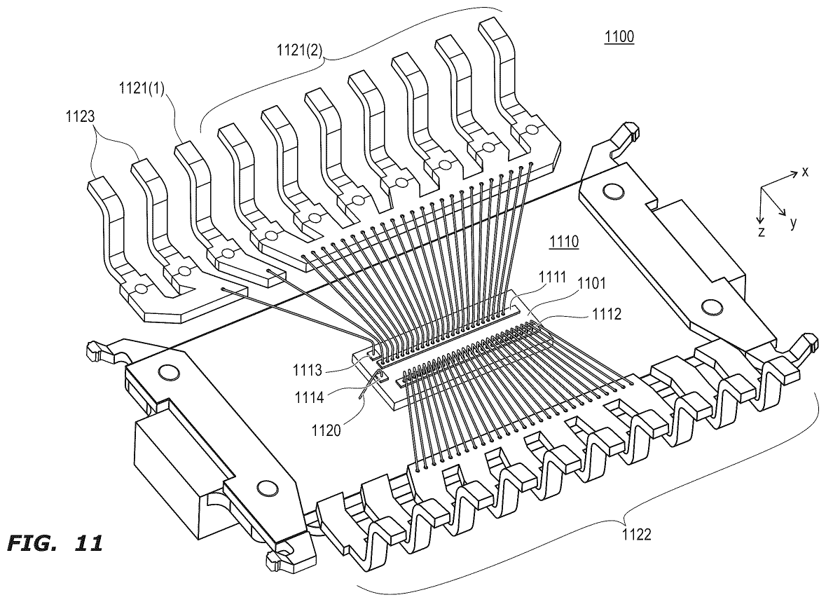

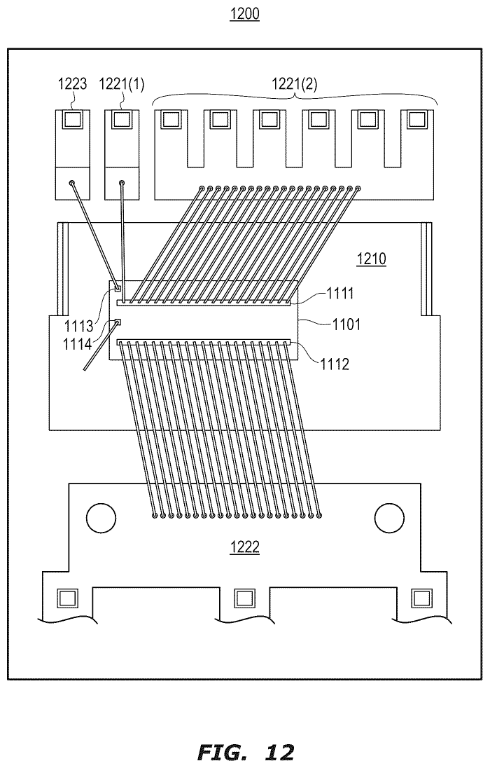

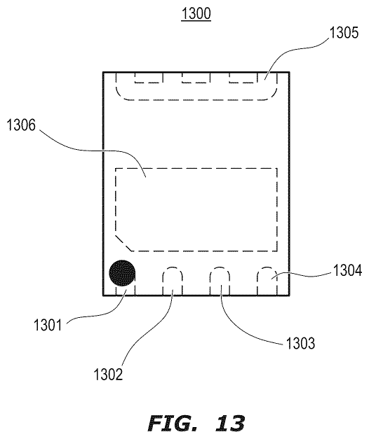

Now several packaging structures and techniques will be described when the substrate biasing is monolithic (on the same die) as the power transistor. FIG. 11 illustrates a PSOP package 1100, FIG. 12 illustrates a TOLL package 1200, and FIG. 13 illustrates a PQFN package 1300. In each case, the package includes a die 1101 in which a power transistor and the biasing circuit are both implemented (though the die is not illustrated in FIG. 13).

FIG. 11 illustrates a PSOP package 1100 that includes the die 1101. The die 1101 is mounted on a conductive base 1110 that represents a part of the lead frame of the PSOP package 1100. The die 1101 includes a source contact 1111 that is wire bonded to a source sense terminal 1121(1) of the lead frame, and that is wire bonded to a source terminal 1121(2) of the lead frame. The die 1101 also includes a drain contact 1112 that is wire bonded to a drain terminal 1122 of the lead frame. The die 1101 further includes a gate contact 1113 that is wire bonded to a gate terminal 1123 of the lead frame.

The die 1101 also includes a substrate bias contact 1114 on which the substrate biasing voltage is applied by the biasing circuit that is internal to the die 1101. In FIG. 11, substrate biasing is completed by a wire 1120 connecting the substrate bias contact 1114 with the conductive base 1110 that is also conductively connected to the substrate of the die 1101. In an alternative embodiment, the bias substrate is applied to the conductive base 1110 through a conductive via formed within the die 1101 itself.

FIG. 12 illustrates a TOLL package in which the die 1101 is packaged. The die 1101 is mounted to a conductive base 1210 of the lead frame of the TOLL package. The source contact 1111 of the die 1101 is wire bonded to a source sense terminal 1221(1) of the lead frame, and is also wire bonded to a source terminal 1221(2) of the lead frame. The drain contact 1112 is wire bonded to a drain terminal 1222 of the lead frame. The gate contact 1113 is wire bonded to a gate terminal 1223 of the lead frame. The substrate bias voltage may be applied to the conductive base 1210 via a wire connected to a substrate bias contact 1114, or instead through a via formed in the die 1101 itself. The TOLL package of FIG. 12 has been modified such that the source contact 1221(2) is electrically disconnected from the conductive base 1210, whereas in a conventional Toll package they are integral.

Substrate biasing may also be performed using a PQFN package. FIG. 13 illustrates a conventional PQFN package 1300 which may be modified to contain the die 1101. The pins 1301 and 1302 are conventionally not used. However, in on embodiment, the pins 1301 and 1302 may be used as source pins, the pin 1303 as a gate pin, the pin 1304 as a source sense pin, and pin 1305 as a drain pin, and the plate 1306 as a substrate contact plate.

### Literal Support Section

Clause 1. A transistor configured to have a dynamically biased substrate alternating between position and negative voltages during operation, the transistor comprising: a barrier semiconductor layer; a channel semiconductor layer immediately beneath the barrier semiconductor layer to form a heterojunction interface with the barrier semiconductor layer, the heterojunction inducing a two-dimensional electron gas (2DEG) within the channel semiconductor layer; a source contact in conductive contact with the 2DEG; a drain contact in conductive contact with the 2DEG; a gate terminal that is proximate to the 2DEG such that voltages applied to the gate terminal control whether the 2DEG is continuous between the source contact and the drain contact; a semiconductor substrate beneath and rigidly coupled to the channel semiconductor layer and the barrier semiconductor layer; a substrate contact layer disposed immediately beneath the semiconductor substrate, the substrate contact layer being electrically disconnected from the source contact to allow for a different voltage to be applied to the substrate contact layer as compared to the source contact; and a biasing circuit configured to bias the semiconductor substrate to a negative bias voltage when the transistor is off.

Clause 2. The transistor in accordance with clause 1, the biasing circuit also configured to bias the substrate to a positive bias voltage when the transistor is on.

Clause 3. The transistor of clause 2, the semiconductor substrate being a Silicon substrate.

Clause 4. The transistor of clause 2, the barrier semiconductor layer being an AlGaN layer, the channel semiconductor layer being a GaN layer.

Clause 5. The transistor of clause 2, the biasing circuit being fabricated sharing portions of the same epitaxial layer as the barrier semiconductor layer and the channel semiconductor layer.

Clause 6. The transistor of clause 2, the biasing circuit being configured such that the positive bias voltage has a maximum voltage of more than 40 Volts.

Clause 7. The transistor of clause 2, the biasing circuit being configured such that the positive bias voltage has a maximum voltage of more than 40 Volts.

Clause 8. The transistor of clause 7, the biasing circuit being configured such that the negative bias voltage has a minimum voltage of less than negative 40 Volts.

Clause 9. The transistor of clause 2, the biasing circuit being configured such that the negative bias voltage has a minimum voltage of less than negative 40 Volts.

Clause 10. The transistor of clause 2, the biasing circuit being configured such that the positive bias voltage has a maximum voltage of more than 100 Volts.

Clause 11. The transistor of clause 2, the biasing circuit being configured such that the negative bias voltage has a minimum voltage of less than negative 100 Volts.

Clause 12. The transistor of clause 2, the biasing circuit being connected to the semiconductor substrate contact layer with a wire that is outside of a die that contains the transistor.

Clause 13. The transistor of clause 2, the channel semiconductor layer and the barrier semiconductor layer formed by epitaxially deposition of an epitaxial stack on the semiconductor substrate, the channel semiconductor layer and the barrier semiconductor layer being formed of a part of the epitaxial stack, the biasing circuit being separate and distinct from the epitaxial stack, the biasing circuit being coupled with the epitaxial stack.

Clause 14. A method for biasing a substrate of a transistor, the transistor having a barrier semiconductor layer, a channel semiconductor layer immediately beneath the barrier semiconductor layer to form a heterojunction interface with the barrier semiconductor layer, the heterojunction inducing a two-dimensional electron gas (2DEG) within the channel semiconductor layer, the transistor further having a source contact in conductive contact with the 2DEG, a drain contact in conductive contact with the 2DEG, a gate terminal that is proximate to the 2DEG such that voltages applied to the gate terminal control whether the 2DEG is continuous between the source contact and the drain contact, a semiconductor substrate beneath and rigidly coupled to the channel semiconductor layer and the barrier semiconductor layer, and a substrate contact layer disposed immediately beneath the semiconductor substrate, the substrate contact layer being electrically disconnected from the source contact to allow for a different voltage to be applied to the substrate contact layer as compared to the source contact, the method further comprising: detecting a pre-condition for applying a negative bias voltage to the substrate contact layer, and in response applying the negative bias voltage to the substrate contact layer.

Clause 15. The method in accordance with Clause 14, the method further comprising detecting a pre-condition for applying a positive bias voltage to the substrate contact layer, and in response applying the positive bias voltage to the substrate contact layer.

Clause 16. The method in accordance with Clause 15, the pre-condition for applying the positive bias voltage being the detection that the transistor has turned on.

Clause 17. The method in accordance with Clause 16, the pre-condition for applying the negative bias voltage being the detection that the transistor has turned off.

Clause 18. The method in accordance with Clause 16, another pre-condition for applying the negative bias voltage being the detection that the transistor has a short.

Clause 19. The method in accordance with Clause 14, the pre-condition for applying the negative bias voltage being the detection that the transistor has turned off.

Clause 20. The method in accordance with Clause 19, another pre-condition for applying the negative bias voltage being the detection that the transistor has a short.

Although the subject matter has been described in language specific to structural features and/or methodological acts, it is to be understood that the subject matter defined in the appended claims is not necessarily limited to the described features or acts described above, or the order of the acts described above. Rather, the described features and acts are disclosed as example forms of implementing the claims.

The present disclosure may be embodied in other specific forms without departing from its essential characteristics. The described embodiments are to be considered in all respects only as illustrative and not restrictive. All changes which come within the meaning and range of equivalency of the claims are to be embraced within their scope.

When introducing elements in the appended claims, the articles “a,” “an,” “the,” and “said” are intended to mean there are one or more of the elements. The terms “comprising,” “including,” and “having” are intended to be inclusive and mean that there may be additional elements other than the listed elements.

What is claimed is:

1. A transistor configured to have a dynamically biased substrate alternating between position and negative voltages during operation, the transistor comprising:
a barrier semiconductor layer;
a channel semiconductor layer immediately beneath the barrier semiconductor layer to form a heterojunction interface with the barrier semiconductor layer, the heterojunction inducing a two-dimensional electron gas (2DEG) within the channel semiconductor layer;
a source contact in conductive contact with the 2DEG;
a drain contact in conductive contact with the 2DEG;
a gate terminal that is proximate to the 2DEG such that voltages applied to the gate terminal control whether the 2DEG is continuous between the source contact and the drain contact;
a semiconductor substrate beneath and rigidly coupled to the channel semiconductor layer and the barrier semiconductor layer;
a substrate contact layer disposed immediately beneath the semiconductor substrate, the substrate contact layer being electrically disconnected from the source contact to allow for a different voltage to be applied to the substrate contact layer as compared to the source contact; and
a biasing circuit configured to bias the semiconductor substrate to a negative bias voltage when the transistor is off.

2. The transistor in accordance with claim 1, the biasing circuit also configured to bias the substrate to a positive bias voltage when the transistor is on.

3. The transistor of claim 2, the semiconductor substrate being a Silicon substrate.

4. The transistor of claim 2, the barrier semiconductor layer being an AlGaN layer, the channel semiconductor layer being a GaN layer.

5. The transistor of claim 2, the biasing circuit being fabricated sharing portions of the same epitaxial layer as the barrier semiconductor layer and the channel semiconductor layer.

6. The transistor of claim 2, the biasing circuit being configured such that the positive bias voltage has a maximum voltage of more than 40 Volts.

7. The transistor of claim 2, the biasing circuit being configured such that the positive bias voltage has a maximum voltage of more than 40 Volts.

8. The transistor of claim 7, the biasing circuit being configured such that the negative bias voltage has a minimum voltage of less than negative 40 Volts.

9. The transistor of claim 2, the biasing circuit being configured such that the negative bias voltage has a minimum voltage of less than negative 40 Volts.

10. The transistor of claim 2, the biasing circuit being configured such that the positive bias voltage has a maximum voltage of more than 100 Volts.

11. The transistor of claim 2, the biasing circuit being configured such that the negative bias voltage has a minimum voltage of less than negative 100 Volts.

12. The transistor of claim 2, the biasing circuit being connected to the semiconductor substrate contact layer with a wire that is outside of a die that contains the transistor.

13. The transistor of claim 2, the channel semiconductor layer and the barrier semiconductor layer formed by epitaxially deposition of an epitaxial stack on the semiconductor substrate, the channel semiconductor layer and the barrier semiconductor layer being formed of a part of the epitaxial stack, the biasing circuit being separate and distinct from the epitaxial stack, the biasing circuit being coupled with the epitaxial stack.

14. A method for biasing a substrate of a transistor, the transistor having a barrier semiconductor layer, a channel semiconductor layer immediately beneath the barrier semiconductor layer to form a heterojunction interface with the barrier semiconductor layer, the heterojunction inducing a two-dimensional electron gas (2DEG) within the channel semiconductor layer, the transistor further having a source contact in conductive contact with the 2DEG, a drain contact in conductive contact with the 2DEG, a gate terminal that is proximate to the 2DEG such that voltages applied to the gate terminal control whether the 2DEG is continuous between the source contact and the drain contact, a semiconductor substrate beneath and rigidly coupled to the channel semiconductor layer and the barrier semiconductor layer, and a substrate contact layer disposed immediately beneath the semiconductor substrate, the substrate contact layer being electrically disconnected from the source contact to allow for a different voltage to be applied to the substrate contact layer as compared to the source contact, the method further comprising:
detecting a pre-condition for applying a negative bias voltage to the substrate contact layer, and in response applying the negative bias voltage to the substrate contact layer.

15. The method in accordance with claim 14, the method further comprising detecting a pre-condition for applying a positive bias voltage to the substrate contact layer, and in response applying the positive bias voltage to the substrate contact layer.

16. The method in accordance with claim 15, the pre-condition for applying the positive bias voltage being the detection that the transistor has turned on.

17. The method in accordance with claim 16, the pre-condition for applying the negative bias voltage being the detection that the transistor has turned off.

18. The method in accordance with claim 16, another pre-condition for applying the negative bias voltage being the detection that the transistor has a short.

19. The method in accordance with claim 14, the pre-condition for applying the negative bias voltage being the detection that the transistor has turned off.

20. The method in accordance with claim 19, another pre-condition for applying the negative bias voltage being the detection that the transistor has a short.
